(19) United States
(12) Patent Application Publication
(10) Pub. No.: US 2008/0083923 A1
(43) Pub. Date: Apr. 10, 2008

(54) SEMICONDUCTOR DEVICE

(75) Inventor: Osamu NAKAUCHI, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/869,025

(22) Filed: Oct. 9, 2007

(30) Foreign Application Priority Data
Oct. 6, 2006 (JP) 2006-274897

(51) Int. Cl. H01L 23/58

(52) U.S. Cl. 257/48; 257/E23.023

(57) ABSTRACT

Provided is a semiconductor device including a bonding pad allowing a probe contact region and a bonding region to be clearly distinguished and thereby controlled. The semiconductor device includes the bonding pad and a slit via region provided to a lower layer of the bonding pad. The slit via region includes a first region on which a plurality of slit vias are disposed in parallel, and a second region including at least one slit via. The width of the slit via of the first region is smaller than that of the slit via of the second region.

### BACKGROUND OF THE INVENTION

1. Field of the Invention

The present invention relates to a semiconductor device provided with a bonding pad.

2. Description of the Related Art

In manufacturing processes of a semiconductor device, a semiconductor device provided with a bonding pad is tested as to its characteristics, and thereafter wiring, which is generally called bonding, is performed. In this bonding process, wiring between a bonding pad of a semiconductor device and a wiring terminal on an insulating substrate is performed using a fine metal wire made of gold or the like, the insulating substrate having inner leads and the semiconductor device mounted thereon. A characteristic test is conducted using a probe card provided with a large number of probes on one surface of the probe card. A characteristic test is conducted while the probes are in contact with the bonding pad of the semiconductor device. At this time, however, the bonding pad may be damaged and the surface thereof may become nonsmooth. In some cases, an aluminum metal forming the bonding pad is peeled off.

Even when bonding is performed on such a damaged surface of the bonding pad, the bonding does not form an alloy layer of a metal wire and the bonding pad. Hence, sufficient connection strength of the bonding cannot be obtained. Accordingly, it is necessary to make a distinction between a probe contact region and a bonding region on the bonding pad, and to control the positioning of a portion of the bonding pad to be touched by the probe in an inspection process. Specifically, the probe contact region is a region where the probe touches the bonding pad in the inspection process, and the bonding region is a region on which bonding is performed. Such positioning can be performed automatically to some extent by use of an image processing technique or the like. However, confirmation and fine adjustment are carried out by an operator actually viewing a bonding pad with a microscope, or by an operator actually viewing an image of the bonding pad, the image having been picked up with a CCD camera or the like.

FIG. 1 shows a top view of a conventional bonding pad 2. On a lower layer of the bonding pad, a plurality of slit vias 4 are provided. The slit vias 4 each have a width of 0.3 μm. When the upper surface of the bonding pad 2 is viewed through a microscope, only the bonding pad 2 having the flat surface is observed.

A probe contact region 6 and a bonding region 8 must be delimited and controlled so that the bonding pad 2 in a longitudinal direction is divided into two parts.

FIG. 2 shows a top view of a conventional bonding pad 10 with notches 12 for controlling the regions. Since an operator can view the notches 12 of the bonding pad 10 using a microscope or the like, a boundary between a probe contact region 14 and a bonding region 16 can be clearly distinguished.

Japanese Patent Application Laid-open Publication No. 2001-338955 discloses a semiconductor device including: a semiconductor chip, a member having a plurality of conductive parts and a fixation part, a plurality of conductive wires and a sealing member. More precisely, on the semiconductor chip, a plurality of bonding pads are disposed so as to form a substantially straight line, and the bonding pads each contain a first region as a connection region and a second region to be touched by a test probe. In addition, the first and second regions of the bonding pad are disposed in a direction intersecting the above straight line. Each of the plurality of conductive parts in the member contains a third region serving as a connection region being electrically connected to a corresponding one of a plurality of external terminals. The fixation part in the member is used to fix the above described semiconductor chip. The plurality of conductive wires electrically connect the first regions of the plurality of bonding pads and the third regions of the plurality of conductive parts, respectively. Then, the sealing member seals the semiconductor chip and the plurality of conductive wires (refer to Japanese Patent Application Laid-open Publication No. 2001-338955).

In the case of the conventional bonding pad 2 shown in FIG. 1, even when viewed through a microscope from above, the bonding pad 2 is observed only as a bonding pad 2 having a flat surface. Hence, a boundary between the probe contact region 6 and the bonding region 8 is not clear. For this reason, it is not easy for an operator to control the positioning of a portion of the bonding pad 2 to be touched by the probe.

On the other hand, in the case of the conventional bonding pad 10 shown in FIG. 2, when the bonding pad 10 is viewed through a microscope, it is possible to view the notches 12 provided to the boundary between the probe contact region 14 and the bonding region 16. Consequently, it is easy for the operator to control the positioning of a portion of the bonding pad 10 to be touched by the probe. However, since the portions corresponding to the areas of the notches 12 are removed from the bonding pad 10, the bonding pad 10 is smaller than otherwise. As a result, the area of the bonding pad 10 to be touched by the probe is smaller, and the area to be joined to metal wires for bonding is also smaller. In other words, the margin for positioning of each component is reduced.

### SUMMARY

Means for solving the problems are described below with numerals used in “DETAILED DESCRIPTION OF THE PREFERRED EMBODIMENTS.” These numerals are added to clarify the correspondence between descriptions of Claims and the “DETAILED DESCRIPTION OF THE PREFERRED EMBODIMENTS.” It is, however, to be noted that these numerals should not be used for understanding the technical scope of the present invention described in the Claims.

According to the present invention, provided is a semiconductor device including a bonding pad (18, 42 and 54) and a slit via region provided to a lower layer of the bonding pad. The slit via region includes a first region (22, 46, 56) on which a plurality of slit vias are disposed in parallel, and a second region (20, 48, 58) including at least one slit via; and the width of a slit via of the first region is smaller than that of a slit via of the second region.

In the semiconductor device, the slit via region further includes a third region (44) in which a plurality of slit vias are disposed in parallel, while the first region (46) and the third region (44) are disposed in parallel. Here, a slit via of the second region (48) is disposed between the first region and the third region so that a longitudinal direction of at least one slit via of the second region is perpendicular to longitudinal directions of a slit via of the first region and a slit via of the third region.

According to the present invention, a semiconductor device including a bonding pad is provided, the bonding pad allowing a probe contact region and a bonding region to be clearly distinguished and thereby controlled.

### BRIEF DESCRIPTION OF THE DRAWINGS

FIG. 1 is a top view of a conventional bonding pad;

FIG. 2 is a top view of another conventional bonding pad with notches for controlling regions;

FIG. 3 is a top view of a bonding pad of a first embodiment of the present invention;

FIG. 4A is a sectional view taken along the line A-A′ of FIG. 3 for illustrating a structure of a semiconductor device of the first embodiment of the present invention;

FIG. 4B is a sectional view taken along the line B-B′ of FIG. 3 for illustrating the structure of the semiconductor device of the first embodiment of the present invention;

FIG. 5 is a top view of a bonding pad of a second embodiment of the present invention; and

FIG. 6 is a top view of a bonding pad of a third embodiment of the present invention.

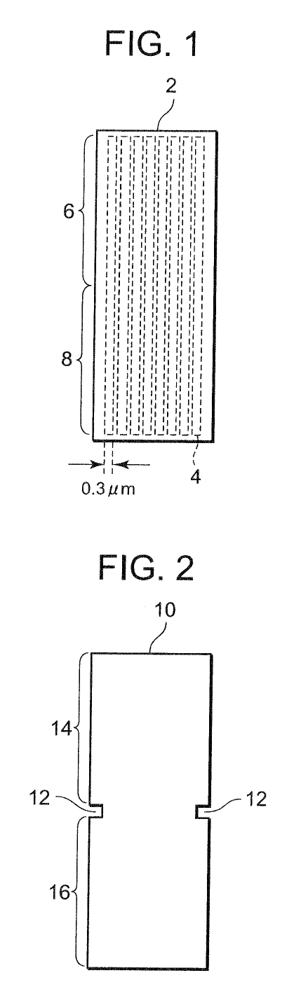

### DETAILED DESCRIPTION OF THE PREFERRED EMBODIMENTS

Embodiments to achieve a semiconductor device of the present invention are described below with reference to the accompanying drawings.

### First Embodiment

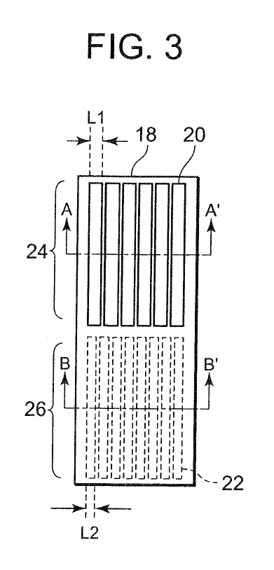

FIG. 3 is a top view of a bonding pad 18 of a first embodiment of the present invention. On a lower layer of the bonding pad 18, a plurality of wide slit vias 20 are disposed in parallel, and a plurality of narrow slit vias 22 are disposed in parallel. When viewing a top surface of the bonding pad 18 using a microscope or the like, it can be seen that a surface of a portion of the bonding pad 18 on which wide slit vias 20 are disposed has a concavity. On the other hand, a surface of a portion of the bonding pad 18 on which narrow slit vias 22 are disposed is flat. Thus, the degree of flatness of a surface of the bonding pad 18 is affected by the width of slit vias on the lower layer, but the detail will be described later. Incidentally, the wide slit via 20 has a width L1 of 1 μm, and the narrow slit via 22 has a width L2 of 0.3 μm. In FIG. 3, the side where the wide slit vias 20 are disposed is set as a probe contact region 24, and the side where the narrow slit vies 22 are disposed is set as a bonding region 26; however, these two sides can be exchanged. In any case, the essential point is to delimit the probe contact region 24 and the bonding region 26.

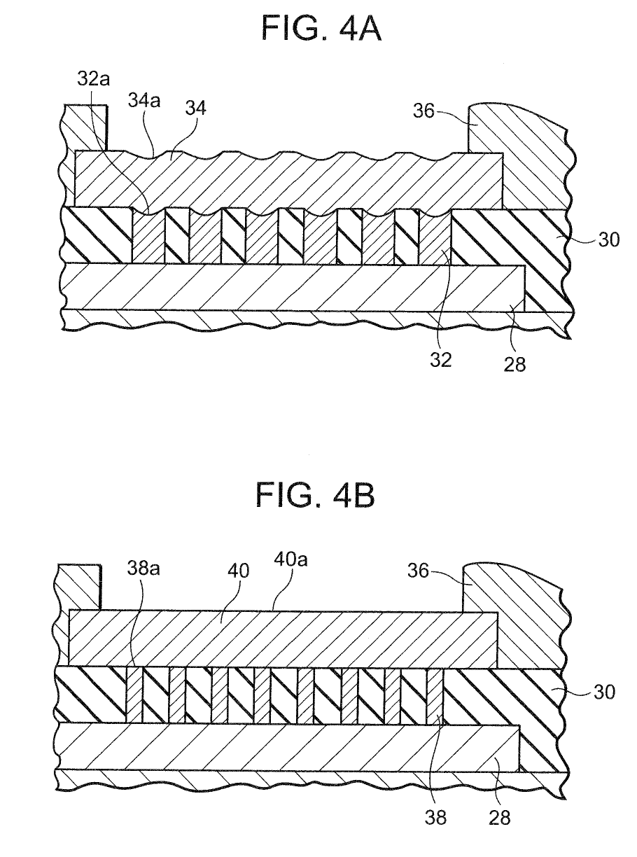

FIG. 4A is a sectional view taken along the line A-A′ of FIG. 3 for illustrating a structure of a semiconductor device of the first embodiment of the present invention. Meanwhile, FIG. 4B is a sectional view taken along the line B-B′ of FIG. 3 for illustrating the structure of the semiconductor device of the first embodiment of the present invention.

In the semiconductor device, on a lower wiring 28 formed of a material such as aluminum, an insulating film 30 formed of a silicon oxide film or the like is formed. Thereafter, using a photolithographic technique or an etching technique, slit vias are provided. Here, a semiconductor device shown in FIG. 4A includes wide slit vias 32 in which the widths of slit vias are set to be large. In the wide slit vias 32, tungsten (W), copper (Cu) or the like are embedded.

On the other hand, the semiconductor device shown in FIG. 4B includes narrow slit vias 38 in which the widths of slit vias are set to be small. In this case also, in the narrow slit vias 32, tungsten (W), copper (Cu) or the like are embedded. Thereafter, an upper surface of the semiconductor device on which the insulating film 30, and the wide slit vias 32 or the narrow slit vias 38 are formed are processed with a polishing process using a chemical mechanical polishing (CMP) method. At this time, because of a difference in hardness between the insulating film 30 and tungsten (W) or copper (Cu) which form the slit vias, a concave is formed in an upper surface 32a of the wide slit via 32 so that a step is produced between the surface 32a and the insulating film 30. No noticeable concave is formed in the narrow slit via 38 on its upper surface 38a so that no step is produced between the upper surface 38a and the insulating film 30. As is clear from FIGS. 4A and 4B, the wide slit vias 32 and the narrow slit vias 38 can be formed on the same layer.

Thereafter, using a sputtering method or the like, a bonding pad 34 or a bonding pad 40 is formed on an upper layer of the slit vias. Although the bonding pad 34 and the bonding pad 40 are integrated, a bonding pad surface 34a or a bonding pad surface 40a is affected by the degree of flatness of the upper surface 32a or the upper surface 38a of the slit vias on the lower layer. The surface 34a of the bonding pad 34 having the wide slit vias 32 on the lower layer has steps, influenced by the steps produced on the upper surface 32a of the slit vias. On the other hand, the surface 40a of the bonding pad 40 having the narrow slit vias 38 on the lower layer is flat, influenced by the degree of flatness of the upper surface 38a of the slit vias.

Therefore, as shown in FIG. 3, when an operator views the surface of the bonding pad 18 using a microscope or the like, he/she can view the steps (concave parts) on the surface of the bonding pad 18 in a region on the side where the wide slit vias 20 are disposed. Hence, the operator can recognize the region as the probe contact region 24 so that he/she can control the positioning of a portion of the bonding pad 18 to be touched by the probe.

To produce the steps on the surface of the bonding pad 18, it is preferable that the wide slit vias 20 each have a width L1 of 0.8 μm or more. Further, not to produce the steps on the surface of the bonding pad 18, it is preferable that the narrow slit vias 22 each have a width L2 of 0.5 μm or less.

### Second Embodiment

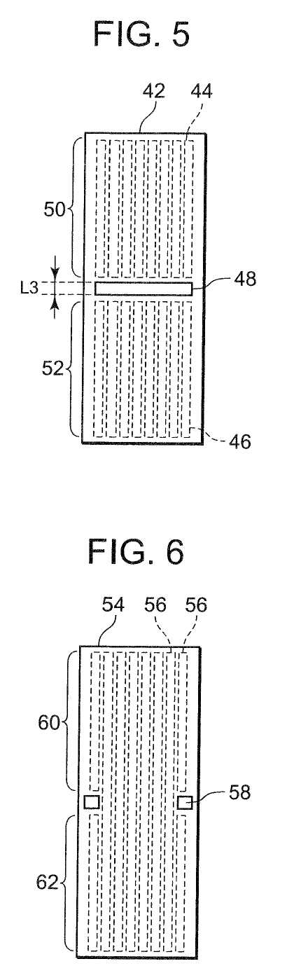

FIG. 5 is a top view of a bonding pad of a second embodiment of the present invention. An outer shape of a bonding pad 42 is rectangular as in the case of the first embodiment. On a lower layer of the bonding pad 42, a group of a plurality of slit vias 44 on the side of a probe contact region, and a group of a plurality of slit vias 46 on the side of a bonding region are disposed. Moreover, a single region separation slit via 48 is disposed on a position between the group of the slit vias 44 on the side of the probe contact region and the group of the slit vias 46 on the side of the bonding region, near the middle of the bonding pad 42 in the longitudinal direction. The region separation slit via 48 has a width L3 of 1 μm, and since an upper surface of the region division slit via 48 is polished by the CMP method as described in the first embodiment, the surface of the region separation slit via 48 has a concavity so that a step is produced, and, consequently, the surface of the bonding pad 42 has a step. Incidentally, the slit vias 44 on the side of the probe contact region and the slit vias 46 on the side of the bonding region may have a width of 1 μm or 0.3 μm. That is, it does not matter whether steps are produced or not on the probe contact region and the bonding region. For example, assume that the widths of the slit vias 44 on the side of the probe contact region and the slit vias 46 on the side of the bonding region are large and that steps are produced on the surface of the bonding pad 42. The steps on the surface of the bonding pad 42 produced by the region separation slit via 48 can be easily noticed since the longitudinal directions of the slit vias 44 on the side of the probe contact region and the slit vias 46 on the side of the bonding region are perpendicular to the longitudinal direction of the region separation slit via 48. Accordingly, when the operator views the bonding pad 42 using a microscope or the like in an inspection step, he/she can clearly view a boundary (steps on the bonding pad 42 produced by the region separation slit via 48) between a probe contact region 50 and a bonding region 52. The operator can control the positioning of a portion of the bonding pad 42 to be touched by the probe. Incidentally, the width of the slit vias 44 on the side of the probe contact region and the width of the slit vias 46 on the side of the bonding region may be the same, or may be different so that one of the widths is larger than the other.

### Third Embodiment

FIG. 6 is a top view of a bonding pad 54 of a third embodiment of the present invention. An outer shape of the bonding pad 54 is rectangular as in the first and second embodiments. On a lower layer of the bonding pad 54, a plurality of slit vias 56 are disposed, and region separation slit vias 58 are disposed in two places on both sides of a position at which the probe contact region 60 and the bonding region 62 are separated, near the middle of the bonding pad 54 in the longitudinal direction. When viewed from above, the region separation slit via 58 is a square with sides of 1 μm. Incidentally, the region separation slit via 58 may be circular with a diameter of 1 μm when viewed from above. Further, the region separation slit via 58 may be disposed in a single place.

Since an upper surface of the region separation slit via 58 is polished by the CMP method as described in the first embodiment, the surface of the region separation slit via 58 has a concavity so that a step is produced. This step affects the surface of the bonding pad 54 to have a step. Therefore, when the operator views an upper surface of the bonding pad 54 using a microscope or the like in an inspection step, he/she can clearly view a boundary (steps on the surface of the bonding pad 54 produced by the region separation slit vias 58) between the probe contact region 60 and the bonding region 62. The operator can control the positioning of a portion of the bonding pad 54 to be touched by the probe.

What is claimed is:

1. A semiconductor device comprising:
a bonding pad; and
a slit via region provided to a lower layer of the bonding pad, wherein
the slit via region includes a first region on which a plurality of slit vies are disposed in parallel, and a second region including at least one slit via, and
the width of the slit via of the first region is smaller than that of the slit via of the second region.

2. The semiconductor device according to claim 1, wherein the bonding pad includes, a concavity on an upper layer of the second region, the concavity depending on a shape of the upper surface of the slit via of the second region.

3. The semiconductor device according to claim 1, wherein a plurality of slit vias are disposed in parallel in the second region.

4. The semiconductor device according to claim 1, wherein the slit via region further includes a third region in which a plurality of slit vias are disposed in parallel,
the first region and the third region are disposed in parallel, and
the at least one slit via of the second region is disposed between the first region and the third region so that a longitudinal direction of the at least one slit via of the second region is perpendicular to longitudinal directions of the slit via of the first region and the slit via of the third region.

5. The semiconductor device according to claim 4, wherein the width of the slit via of the first region is the same as that of the slit via of the third region.

6. The semiconductor device according to claim 1, wherein the at least one slit via of the second region is disposed at a position dividing the plurality of slit vias of the first region in a longitudinal direction into two parts, the slit vias being disposed in parallel.

7. The semiconductor device according to claim 3, wherein:
the first region is for one of probe contact region of the bonding pad and bonding region of the bonding pad, and
the second region is for the other of the probe contact region of the bonding pad and the bonding region of the bonding pad.

8. The semiconductor device according to claim 4, wherein:
the first region is for one of probe contact region of the bonding pad and bonding region of the bonding pad, and
the third region is for the other of the probe contact region of the bonding pad and the bonding region of the bonding pad.

9. The semiconductor device according to claim 1, wherein the slit via regions are disposed on the same layer.

10. The semiconductor device according to claim 1, wherein a slit via of the first region and a slit via of the second region are formed of any one of tungsten and copper.

11. The semiconductor device according to claim 4, wherein a slit via of the third region is formed of any one of tungsten and copper.

12. A semiconductor device comprising at least one first via, a plurality of second vias, and a bonding pad formed to cover the first and second vias in contact therewith, the first via being different in width from each of the second vias.

13. The semiconductor device according to claim 12, wherein the bonding pad has a bonding region and a probe contact region, the first via being provided below one of the bonding and probe contact regions of the bonding pad, and the second vias being provided below of the other of the bonding and probe contact regions of the bonding pad.

14. The semiconductor device according to claim 12, wherein the bonding pad has a bonding region and a probe contact region, the first via being provide below a region between the bonding and probe contact regions of the bonding pad, and the second vias being provided below at least one of the bonding and probe contact regions of the bonding pad.

15. A semiconductor device comprising a semiconductor body and a bonding pad, over the semiconductor body, the bonding pad having a bonding region and a probe contact region, and the bonding pad further having at least one concavity to distinguish the bonding region and the probe contact region from each other.
